(19) United States
(12) Patent Application Publication
(10) Pub. No.: US 2009/0140232 A1
(43) Pub. Date: Jun. 4, 2009

(54) Resistive Memory Element

(76) Inventor: Klaus-Dieter Ufert, Unterschleissheim (DE)

Correspondence Address: SLATER & MATSIL, L.L.P., 17950 PRESTON ROAD, SUITE 1000, DALLAS, TX, 75252, US

(21) Appl. No.: 11/948,724

(22) Filed: Nov. 30, 2007

(51) Int. Cl. H01L 45/00

(52) U.S. Cl. 257/4; 438/102; 438/104; 257/E45.002

(57) ABSTRACT

An integrated circuit including a resistive memory element is described. The resistive memory element includes a first solid electrolyte layer including a metal doped glass material, the glass material being at least partially amorphous, and a second solid electrolyte layer including the metal doped glass material. The resistive memory element also includes a middle layer disposed between the first and second solid electrolyte layers, the middle layer including a carbide composition.

### BACKGROUND

Memory devices are used in essentially all computing applications and in many electronic devices. For some applications, non-volatile memory, which retains its stored data even when power is not present, may be used. For example, non-volatile memory is typically used in digital cameras, portable audio players, wireless communication devices, personal digital assistants, and peripheral devices, as well as for storing firmware in computers and other devices.

A wide variety of memory technologies have been developed. Non-volatile memory technologies include flash memory, magnetoresistive random access memory (MRAM), phase change random access memory (PCRAM), and conductive bridging random access memory (CBRAM). Due to the great demand for memory devices, researchers are continually improving memory technology, and developing new types of memory, including new types of non-volatile memory.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A and 1B show a conventional conductive bridging memory element;

FIGS. 2A and 2B show alternative block diagram layouts of a memory cell using a conductive bridging memory element;

FIG. 3 shows a conductive bridging resistive memory element including a multi-layer matrix in accordance with an embodiment of the invention;

FIG. 4 is a graph showing the resistance of a three layer system having a GeSe:N middle layer, in accordance with an embodiment of the invention;

FIG. 5 is a block diagram of a method for fabricating a conductive bridging resistive memory element having a multi-layer matrix in accordance with an embodiment of the invention;

FIGS. 6A and 6B show memory elements in accordance with an embodiment of the invention at different stages of the fabrication process;

FIG. 7 shows a cross section of an integrated circuit memory device in accordance with an embodiment of the invention;

FIG. 8 is a block diagram of a method of storing information in accordance with an embodiment of the invention;

FIGS. 9A-9F show steps in the formation of a bottom contact that may be used with a memory element in accordance with an embodiment of the invention; and

FIGS. 10A and 10B show a memory module and a stackable memory module, respectively, which may use memory elements in accordance with an embodiment of the invention.

### DETAILED DESCRIPTION OF ILLUSTRATIVE EMBODIMENTS

The scale of electronic devices is constantly being reduced. For memory devices, conventional technologies, such as flash memory and DRAM, which store information based on the storage of electric charges, may reach their scaling limits in the foreseeable future. Additional characteristics of these technologies, such as the high switching voltages and limited number of read and write cycles of flash memory, or the limited duration of the storage of the charge state in DRAM, pose additional challenges. To address some of these issues, researchers are investigating memory technologies that do not use storage of an electrical charge to store information. One such technology is conductive bridging random access memory (CBRAM).

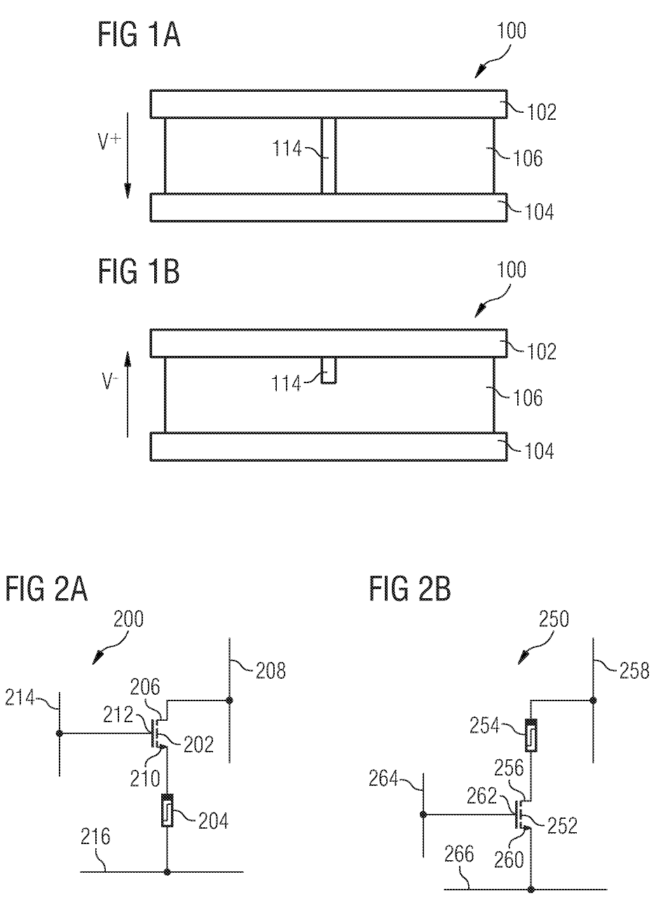

FIG. 1A shows a conventional conductive bridging junction (CBJ) for use in a CBRAM cell. A CBJ 100 includes a first electrode 102, a second electrode 104, and a solid electrolyte block 106 sandwiched between the first electrode 102 and the second electrode 104. One of the first electrode 102 and the second electrode 104 is a reactive electrode, the other is an inert electrode. In this example the first electrode 102 is the reactive electrode, and the second electrode 104 is the inert electrode. The first electrode 102 includes silver (Ag) in this example, and the solid electrolyte block 106 includes a silver-doped chalcogenide glass material.

When a voltage is applied across the solid electrolyte block 106, a redox reaction is initiated that drives Ag+ ions out of the first electrode 102 into the solid electrolyte block 106 where they are reduced to Ag, thereby forming Ag rich clusters within the solid electrolyte block 106. The size and the number of Ag rich clusters within the solid electrolyte block 106 may be increased to such an extent that a conductive bridge 114 between the first electrode 102 and the second electrode 104 is formed.

As shown in FIG. 1B, when an inverse voltage to that applied in FIG. 1A is applied across the solid electrolyte 106, a redox reaction is initiated that drives Ag+ ions out of the solid electrolyte block 106 into the first electrode 102 where they are reduced to Ag. As a consequence, the size and the number of Ag rich clusters within the solid electrolyte block 106 is reduced, thereby reducing, and eventually removing the conductive bridge 114.

To determine the current memory state of the CBJ 100, a sensing current is routed through the CBJ 100. The sensing current encounters a high resistance if no conductive bridge 114 exists within the CBJ 100, and a low resistance when a conductive bridge 114 is present. A high resistance may, for example, represent “0”, while a low resistance represents “1”, or vice versa.

The solid electrolyte block 106 can include many materials, but the materials of greatest interest for use in CBRAM are the chalcogens, including oxygen (O), sulphur (S), and selenium (Se). Combining these with copper (Cu) or silver (Ag) yields binary electrolytes, such as Ag₂Se or Cu₂S. Alternatively, a transition metal, such as tungsten (W) can be reacted with oxygen to form a suitable base glass for an electrolyte. If, for example, the resulting tungsten oxide is sufficiently porous and in its trioxide form (WO₃), silver or copper ions will be mobile within the material, and can form electrodeposits. Another approach is to combine chalcogens with other elements, such as germanium, to create a base glass into which Cu or Ag may be dissolved. An example of such an electrolyte is Ag dissolved in Ge₃₀Se₇₀ (e.g., Ag₃₃Ge₂₀Se₄₇). This takes the form of a continuous glassy Ge₂Se₃ backbone and a dispersed Ag₂Se phase, which is superionic and allows the electrolyte to exhibit superionic qualities. The nanostructure of this material, and of its sulphide counterpart, provide good characteristics for use in switching devices, such as CBRAM. The metal-rich phase is both an ion and an electron conductor, but the backbone material that separates each of these conducting regions is a good dielectric, so the overall resistance of the material prior to electrodeposition is high. Generally, a germanium selenide (GeSe) compound or germanium sulfide (GeS) compound is used in conventional CBRAM devices, but silicon selenide and silicon sulfide may also be used. Although the example embodiments of the invention below are generally described in terms of a GeSe or GeS device, it will be understood that the principles of the invention may be employed in CBRAM devices that use silicon selenide or sulfide, or other suitable chalcogenide glasses.

A solid electrolyte, such as those used in CBRAM, can be made to contain ions throughout its thickness. The ions nearest the electron-supplying cathode will move to its surface and be reduced first. Non-uniformities in the ion distribution and in the nano-topography of the electrode will promote localized deposition or nucleation. Even if multiple nuclei are formed, the one with the highest field and best ion supply will be favored for subsequent growth, extending out from the cathode as a single metallic nanowire. The electrodeposition of metal on the cathode physically extends the electrode into the electrolyte, which is possible in solid electrolytes, particularly if they are amorphous or partially amorphous, and are able to accommodate the growing electrodeposit in a void-rich, semi-flexible structure.

Because the electrodeposit is connected to the cathode, it can supply electrons for subsequent ion reduction. This permits the advancing electrodeposit to harvest ions from the electrolyte, plating them onto its surface to extend itself forward. Thus, in an electrolyte containing a sufficient percentage of metal ions, the growing electrodeposit is always adjacent to a significant source of ions, so the average distance each ion travels in order to be reduced is, at most, a few nm.

The resistivity of the electrodeposit is orders of magnitude lower than that of the surrounding electrolyte, so once the electrodeposit has grown from the cathode to the anode, forming a complete conductive bridge, the resistance of the structure drops considerably. The decreasing resistance of the structure due to the electrodeposition effect increases the current flowing through the device until the current limit of the source is reached. At this point, the voltage drop falls to the threshold for electrodeposition, and the process stops, yielding the final “on” resistance of the structure.

As noted above, the electrodeposition process is reversible by changing the polarity of the applied bias. If the electrodeposit is made positive with respect to the original oxidizable electrode, it becomes the new anode, and will dissolve via oxidation. During the dissolution of the conductive bridge, balance is maintained by electrodeposition of metal back into the place where the excess metal for the electrodeposition originated. The original growth process of the conductive bridge will have left a low ion density region in the electrolyte surrounding the electrode, and this “free volume” will favor redeposition without extended growth back into the electrolyte. Once the electrodeposit has been completely dissolved, the process will self-terminate, yielding the final “off” resistance of the structure. The asymmetry of the structure facilitates the cycling of the device between a high-resistance “off” state, and a low-resistance “on” state, permitting the device to operate as a switch or memory element.

FIG. 2A shows an illustrative memory cell that uses a memory element such as the CBJ shown in FIGS. 1A-1B or a memory element in accordance with the invention, as described hereinbelow. The memory cell 200 includes a select transistor 202 and a memory element 204. The select transistor 202 includes a first source/drain 206 that is connected to a bit line 208, a second source/drain 210 that is connected to the memory element 204, and a gate 212 that is connected to a word line 214. The memory element 204 is also connected to a common line 216, which may be connected to ground, or to other circuitry, such as circuitry (not shown) for determining the resistance of the memory cell 200, for use in reading. Alternatively, in some configurations, circuitry (not shown) for determining the state of the memory cell 200 during reading may be connected to the bit line 208. It should be noted that as used herein the terms connected and coupled are intended to include both direct and indirect connection and coupling, respectively.

To write to the memory cell, the word line 214 is used to select the cell 200, and a current on the bit line 208 is forced through the memory element 204, to form or remove a conductive bridge in the memory element 204, changing the resistance of the memory element 204. Similarly, when reading the cell 200, the word line 214 is used to select the cell 200, and the bit line 208 is used to apply a voltage across the memory element 204 to measure the resistance of the memory element 204.

The memory cell 200 may be referred to as a 1T1J cell, because it uses one transistor, and one memory junction (the memory element 204). Typically, a memory device will include an array of many such cells. It will be understood that other configurations for a 1T1J memory cell, or configurations other than a 1T1J configuration may be used with a CBRAM or memory element such as is shown in FIGS. 1A and 1B, or a resistive memory element in accordance with the invention, as described below. For example, in FIG. 2B, an alternative arrangement for a 1T1J memory cell 250 is shown, in which a select transistor 252 and a memory junction 254 have been repositioned with respect to the configuration shown in FIG. 2A.

In the alternative configuration shown in FIG. 2B, the memory element 254 is connected to a bit line 258, and to a first source/drain 256 of the select transistor 252. A second source/drain 260 of the select transistor 252 is connected to a common line 266, which may be connected to ground, or to other circuitry (not shown), as discussed above. A gate 262 of the select transistor 252 is controlled by a word line 264.

Use of amorphous or partially amorphous solids such as GeSe and GeS glasses in CBRAM devices presents numerous challenges. First, the resistance of these materials is very high when the device is in its “off” state, approximately 10¹¹ to 10¹² ohms at room temperature. This high off resistance (R_{off}) can lead to problems of interference. A node in a CBRAM cell located between the CBJ and the transistor (which has an R_{off} of approximately 10¹⁰ ohms when switched off) is essentially floating when both the CBJ and transistor are off, and is extremely sensitive to interference from sources such as capacitive coupling. Additionally, even very low leakage currents, for example, in the select transistors, may cause the buildup of interference voltages. Many other sources, such as static charges that may build up on plastic packages, may also cause interference effects. These interference effects can lead to inadvertent programming (switching) of the CBJ.

Another challenge in the use of amorphous or partially amorphous materials such as germanium selenide and germanium sulfide in CBRAM devices is the poor temperature stability of such materials. In particular, these materials may start to change from an amorphous or partially amorphous phase to a crystal phase at temperatures as low as 250° C. to 280° C. In a crystal phase, the migration of ions in the material becomes more difficult, which can lead to failure of the memory device. The temperatures reached during the back-end-of-line (BEOL) CMOS process may be as high as 400° C. or 450° C. These temperatures are too high for the chalcogenide glasses that are used in conventional CBRAM devices, and may lead, for example, to the material changing to the crystal phase. Attempts to improve the temperature stability of CBRAM devices by doping with oxygen have resulted in devices in which the Ag ions have insufficient ability to diffuse through the matrix, leading to devices that may be unable to retain an on-state.

In accordance with an embodiment of the invention, a multi-layer matrix may be used in an integrated circuit CBRAM device to provide a reduced R_{off}, resulting in decreased susceptibility to interference in a dense memory array. Additionally, depending on the materials used in the layers, a multi-layer matrix CBRAM device in accordance with an embodiment of the invention may provide improved temperature stability, without substantially hindering Ag-ion diffusion.

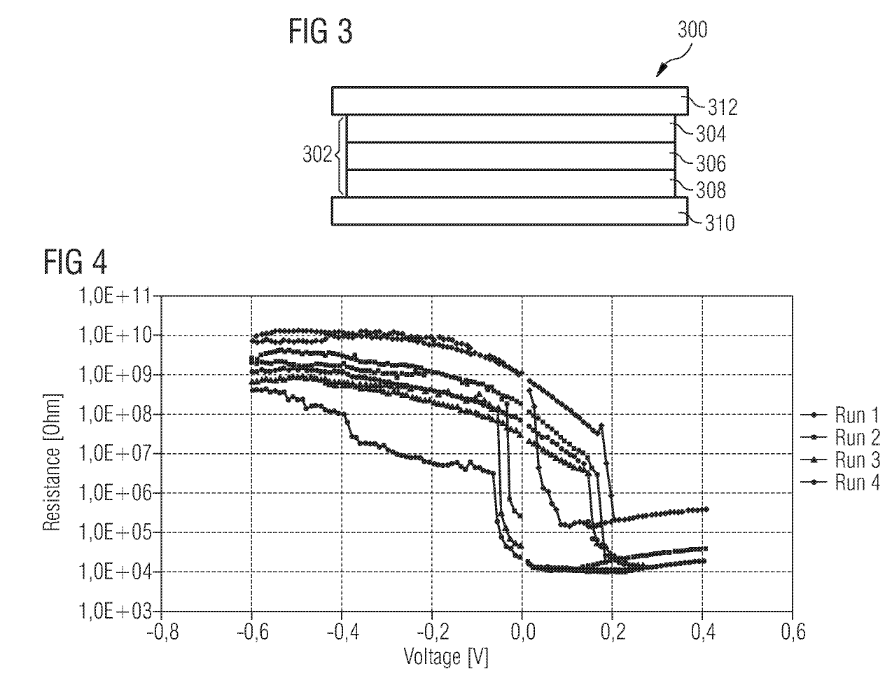

As shown in FIG. 3, an example of a conductive bridging resistive memory element 300 in accordance with an embodiment of the invention uses a triple layer matrix 302, in which a middle layer 306 includes a carbide composition, such as germanium carbide (GeC) or silicon carbide (SiC). Thus, where the chalcogenide glass that is used for the resistive memory element 300 is GeSe (or, alternatively, GeS), the middle layer 306 may include GeC, as well as Se (or S), in forms such as GeSe:C (or GeS:C), particularly at the interfaces (which may form interface layers) between the middle layer 306 and the upper and/or lower layers 304 and 308. Where the chalcogenide glass is a silicon selenide or silicon sulfide compound, then the middle layer 306 may, for example, include SiC, as well as various Se (or S) impurities.

The upper layer 304 and lower layer 308 include GeSe (or GeS) or another suitable solid electrolyte material, such as a chalcogenide glass or other amorphous or partially amorphous material. The layers 304, 306 and 308 of the resistive memory element 300 are also doped with Ag (or another suitable metal). The resistive memory element 300 also includes an inert electrode 310, including tungsten (W) or another suitable conductive material, and a reactive electrode 312, including Ag, or another metal, depending on the metal with which the CBJ 300 is doped.

To permit the penetration of Ag ions through the middle layer 306, the middle layer 306 should have a thickness between approximately 3 and 20 nm, and preferably between approximately 10 and 20 nm. The middle layer 306 may have a thickness greater than about 20 nm, but a higher threshold voltage will generally be needed to permit penetration of Ag ions through a layer that is substantially thicker than about 20 nm. Additionally, although the example embodiment shown in FIG. 3 has three layers, it will be understood that other embodiments having a greater number of layers, in which GeSe (or GeS) layers are alternated with layers containing carbide compositions, such as GeC or SiC, such as the middle layer 306.

The carbide composition middle layer 306 serves to reduce the R_{off} for the resistive memory element 300, reducing the susceptibility of a memory cell constructed in accordance with an embodiment of the invention to interference, and improving the suitability of such a memory cell for use in a dense array. Additionally, carbide compositions such as those used in the middle layer 306 may have a high recrystallization temperature. For example, GeC has a recrystalizytion temperature higher than 700° C. This may permit the middle layer 306 to serve as a barrier layer for crystallization, preventing crystallization in the upper layer 304 and the lower layer 308, neither of which has sufficient thickness to permit crystallization when separated from the other by the middle layer 306. This increases the temperature stability of the resistive memory element 300.

Due to the chemical nature of carbon, the diffusion of Ag through the middle layer 306 will be hindered only slightly, if at all. For example, this may be because the four valence electrons of the carbon fit well to a Ge central atom. Additionally, carbon does not generally bond with Ag. As a result of these properties, there is little (if any) disturbance to the retention of the on-state due to the introduction of the middle layer 306. It will be understood that although these properties may be useful, the invention is not limited to a particular theory of operation, and other materials may be used in accordance with the principles of the invention.

The resistance, including R_{off}, of the middle layer 306 may be adjusted by varying the composition of the middle layer 306. For example, a middle layer 306 that includes GeSe (or GeS), as well as GeC, may form GeSe:C (or GeS:C) impurities, which may reduce the resistance. Generally, a higher carbon content will cause a greater number of such impurities or defects in the material, which may cause leakage currents, leading to a reduced R_{off}. It should be noted that materials other than carbon can be used to provide this reduced R_{off} effect due to impurities and/or defects in the material. For example, nitrogen (N) may be used, to form a multi-layer system having GeSe:N impurities in the middle layer, between layers of GeSe. The resistance of such a nitrogen-containing triple layer system is shown in FIG. 4. As can be seen in FIG. 4, in which the resistance of a three layer system having GeSe top and bottom layers of about 20 nm each and a GeSe:N middle layer of about 20 nm is shown, the value of R_{off} is generally in the range of approximately 10⁷ to 10¹⁰ ohms, between two and five orders of magnitude lower than the R_{off} of 10¹¹ to 10¹² ohms that are typically encountered in a conventional CBRAM cell. FIG. 4 also shows a much lower resistance, generally in the range of approximately 10⁴ to 10⁶ ohms when a conductive bridge has been formed.

Because the layers are effectively connected in series electrically, reducing the resistivity of one of the layers will reduce the resistivity of the entire multi-layer system. Thus, by using carbon or nitrogen impurities to reduce the R_{off} of the middle layer, the R_{off} for the entire memory element is reduced.

Referring now to FIG. 5, an example of a method of manufacturing an integrated circuit including a multi-layer matrix in accordance with an embodiment of the invention is described. It will be understood that the manufacturing of such a device may be accomplished by any method known in the art or hereafter developed that is suitable for forming the inventive structure. Additionally, although the method describes use of a silver doped germanium selenide as a solid electrolyte, and a carbide composition, such as GeC in the middle layer, it should be recognized that the steps described below could be used with different sputtering targets to produce a similar device using different materials. For example, as discussed above, the solid electrolyte may include germanium sulfide, silicon selenide, or silicon sulfide instead of germanium selenide, and the carbide composition could be silicon carbide, or other carbide compositions, rather than germanium carbide.

As described, the method starts with wafers onto which select transistors, vias, an isolation layer, and bottom electrode (typically containing tungsten) have already been deposited. Thus, the method described with reference to FIG. 5 shows only the manufacture of the multi-layer matrix, and deposition of the top (reactive) electrode. Advantageously, the manufacture of a multi-layer matrix in accordance with the invention can be achieved without substantially altering the flow of the process or the equipment used in the manufacture of conventional CBRAM devices.

In step 502, a GeSe target, a GeC target, and an Ag target are installed in sputter equipment that is capable of using at least three sputter targets without disrupting the vacuum. Many commonly used sputter deposition devices, such as some of the models manufactured by Canon ANELVA Corporation, of Tokyo, Japan, have this capability.

In step 504, a first GeSe layer is deposited. This layer may be deposited by means of RF-magnetron sputtering, or other suitable sputtering techniques. In the case of RF-magnetron sputtering, typically Ar is used as a sputter gas, at a pressure of approximately 4.5×10⁻³ mbar and an HF-sputter power in the range of approximately 1 to 2 kW. In some embodiments, this layer is deposited into pre-manufactured vias or on a W-plug of the memory element, and may have a thickness of approximately 20 nm, though a different thickness may be used (though if the thickness is great enough to permit crystallization, some of the temperature stability benefits may be lost).

In step 506, the GeC middle layer is deposited by RF sputtering the GeC target. This sputtering can be done under similar conditions to those in step 504, but with the power reduced to approximately 500 W to 1 kW (though other powers may be used). As discussed above, the thickness of the middle layer produced in this step should be between approximately 3 and 20 nm, and preferably between approximately 10 and 20 nm, though greater thickness is possible. Optionally, the GeC target may be co-sputtered together with the GeSe target, to provide GeSe:C impurities in the middle layer. Optionally, in some embodiments, a dense electron-cyclotron-wave resonance (ECWR) plasma may be generated by exciting and ionizing carbon atoms, to enhance the reactivity of the carbon atoms.

In step 508, a second layer of GeSe is deposited, using a process similar or identical to that used in step 504. The thickness of this layer may be approximately 20 nm, though a different thickness may be used. This would give the triple-layer matrix an approximate thickness of 50 to 60 nm, though this will vary with the thickness of the layers.

In step 510, the doping material Ag is deposited, and in step 512, the Ag doping material is diffused into the matrix by, for example, photodiffusion.

In step 514, the memory element is completed by depositing the Ag top electrode. This may be done, for example, by DC magnetron sputtering from an Ag target in a noble gas.

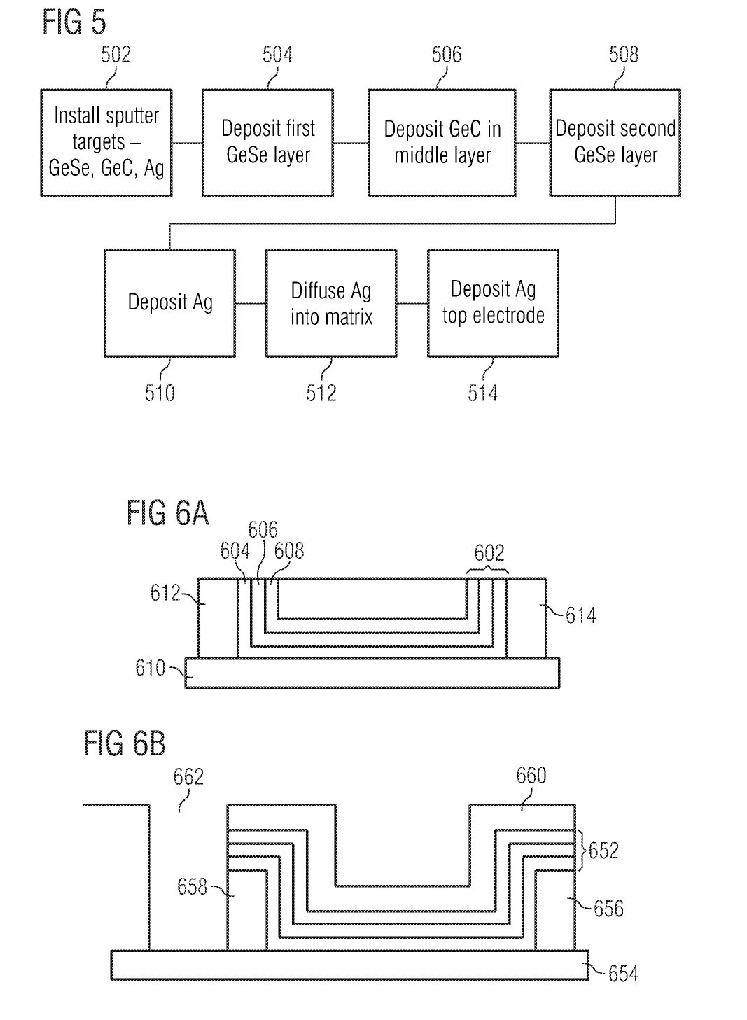

FIG. 6A shows an example view of a triple layer matrix in accordance with the invention prior to step 510, in which the matrix is doped with Ag. The triple-layer matrix 602 includes a first GeSe layer 604, a carbide composition middle layer 606, and a second GeSe layer 608. The triple-layer matrix 602 has been deposited above a tungsten (W) bottom electrode 610, and between dielectric spacers 612 and 614. In FIG. 6B, a similar view is shown after step 514, in which the top electrode is deposited. The Ag-doped triple-layer matrix 652 has deposited above a W bottom electrode 654, and between dielectric spacers 656 and 658. The Ag-doped triple-layer matrix 652 is topped by an Ag top electrode 660. A contact hole 662 will permit contact to be made to the bottom electrode 654.

Referring to FIG. 7, a cross section of two memory cells of a completed integrated circuit including a CBRAM device in accordance with an embodiment of the invention is shown. As can be seen, the integrated circuit 700 includes word lines 702 and 704, which connect to the gates of select transistors 706 and 708. A shared drain 710 of select transistors 706 and 708 is connected to a common line 712, which may be connected to ground. The source region 714 of select transistor 706 and the source region 716 of select transistor 708 are connected to conductive bridging resistive memory elements 718 and 720, respectively. Each of the resistive memory elements 718 and 720 has a bottom electrode, a multi-layer matrix in accordance with an embodiment of the invention, and a top electrode. The resistive memory elements 718 and 720 are connected to a bit line 722.

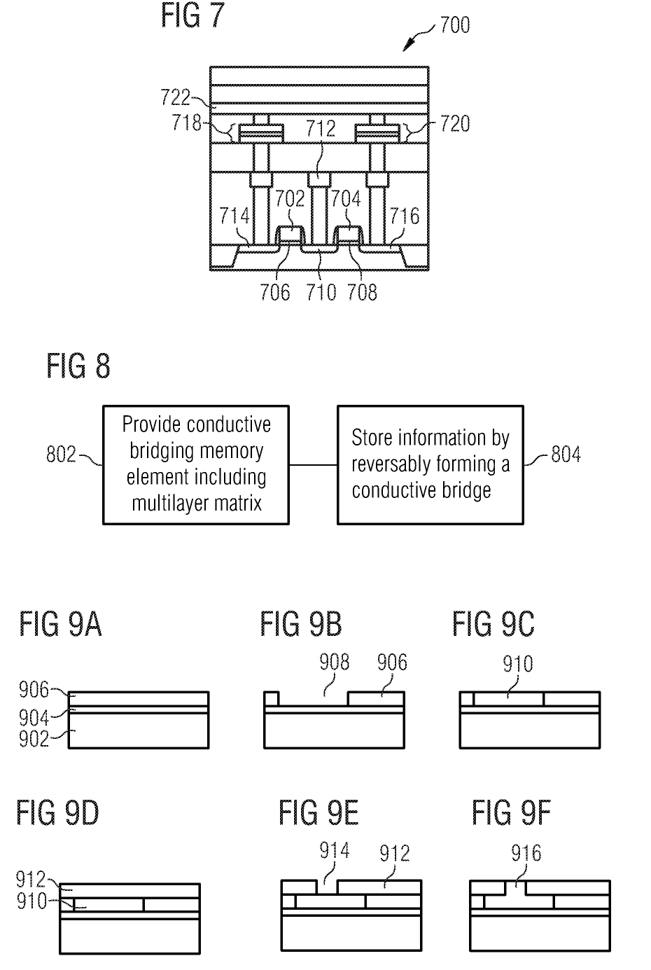

Referring now to FIG. 8, a method of storing information in accordance with an embodiment of the present invention is described. In step 802, a conductive bridging resistive memory element including a multi-layer matrix, as described above with reference to FIG. 3, is provided. The multi-layer matrix includes at least a first solid electrolyte layer, a middle layer, and a second solid electrolyte layer. As discussed above, the middle layer contains a carbide composition, such as GeC, to increase the temperature stability of the resistive memory element, and to reduce its off resistance.

In step 804, information is stored in the resistive memory element by reversibly forming a conductive bridge through the first solid electrolyte layer, the middle layer, and the second solid electrolyte layer, as described hereinabove.

Referring to FIGS. 9A-9F, example steps in an integrated circuit fabrication process for constructing a bottom contact for use with a CBRAM memory element are described. It will be understood that this process, and the bottom contact that is created using it, may be used with a conventional CBRAM element, as well as a conductive bridging resistive memory element according to various embodiments of the invention. It will further be recognized that a resistive memory element according to various embodiments of the invention is not limited to using a bottom contact constructed by such a process, but may use any suitable bottom contact, constructed by any process now known or later developed.

FIG. 9A shows an oxide layer 902 onto which a nitride etch stop 904 has been deposited, as well as an additional oxide layer 906. As shown in FIG. 9B, a lithographic process and etching is used to create a trench 908 in the oxide layer 906 for the bottom contact.

FIG. 9C shows a conductive material 910, such as W, deposited in the trench 908 of FIG. 9B, and planarized, for example, by a chemical mechanical planarization process.

In FIG. 9D, a nitride/oxide layer 912 has been deposited over the conductive material 910. As shown in FIG. 9E, a lithographic process and etching are used to form a hole 914 in the nitride/oxide layer 912.

Next, as shown in FIG. 9F, the hole 914 is filled with a conductive material, such as TiN/W or another suitable material, and planarized, completing construction of a bottom contact 916. Once the bottom contact has been deposited, a method such as is described above with reference to FIG. 5 may be used to construct a CBRAM memory element in accordance with an embodiment of the invention.

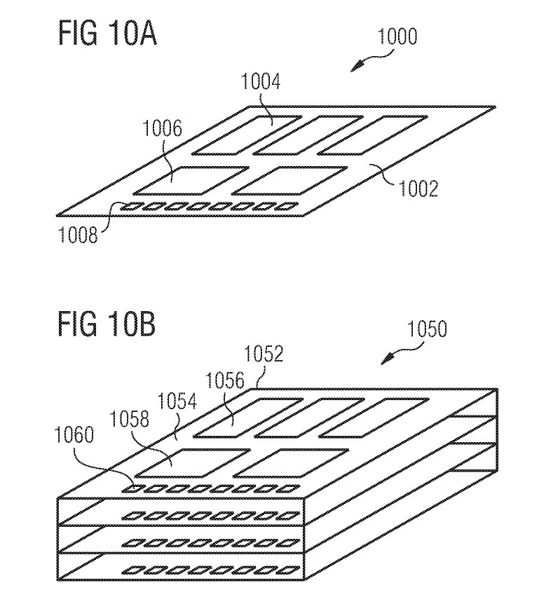

Memory cells including memory elements such as those described above may be used in memory devices that contain large numbers of such cells. These cells may, for example, be organized into an array of memory cells having numerous rows and columns of cells, each of which stores one or more bits of information. Memory devices of this sort may be used in a variety of applications or systems. As shown in FIGS. 10A and 10B, in some embodiments, memory devices such as those described herein may be used in modules. In FIG. 10A, a memory module 1000 is shown, on which one or more memory devices 1004 are arranged on a substrate 1002. Each memory device 1004 may include numerous memory cells in accordance with an embodiment of the invention. The memory module 1000 may also include one or more electronic devices 1006, which may include memory, processing circuitry, control circuitry, addressing circuitry, bus interconnection circuitry, or other circuitry or electronic devices that may be combined on a module with a memory device 1004. Additionally, the memory module 1000 includes multiple electrical connections 1008, which may be used to connect the memory module 1000 to other electronic components, including other modules. For example, the module 1000 may be plugged into a larger circuit board, including PC main boards, video adapters, cell phone circuit boards or portable video or audio players, among others.

As shown in FIG. 10B, in some embodiments, these modules may be stackable, to form a stack 1050. For example, a stackable memory module 1052 may contain one or more memory devices 1056, arranged on a stackable substrate 1054. Each of the memory devices 1056 contains memory cells that employ memory elements in accordance with an embodiment of the invention. The stackable memory module 1052 may also include one or more electronic devices 1058, which may include memory, processing circuitry, control circuitry, addressing circuitry, bus interconnection circuitry, or other circuitry or electronic devices that may be combined on a module with a memory device 1056. Electrical connections 1060 are used to connect the stackable memory module 1052 with other modules in the stack 1050, or with other electronic devices. Other modules in the stack 1050 may include additional stackable memory modules, similar to the stackable memory module 1052 described above, or other types of stackable modules, such as stackable processing modules, control modules, communication modules, or other modules containing electronic components.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising:
a resistive memory element comprising a first solid electrolyte layer comprising a metal doped glass material, the metal doped glass material being at least partially amorphous;
a second solid electrolyte layer comprising the metal doped glass material; and
a middle layer disposed between the first and second solid electrolyte layers, the middle layer comprising a carbide composition.

2. The integrated circuit of claim 1, wherein the carbide composition comprises germanium carbide or silicon carbide.

3. The integrated circuit of claim 1, wherein the middle layer further comprises the metal doped glass material.

4. The integrated circuit of claim 3, wherein the metal doped glass material in the middle layer comprises impurities that reduce an off resistance of the resistive memory element.

5. The integrated circuit of claim 4, wherein the impurities comprise carbon impurities or nitrogen impurities.

6. The integrated circuit of claim 1, wherein the metal doped glass material comprises a germanium selenide compound, a germanium sulfide compound, a silicon selenide compound or a silicon sulfide compound.

7. The integrated circuit of claim 1, wherein the middle layer has a thickness of between approximately 3 and approximately 20 nm.

8. The integrated circuit of claim 7, wherein the middle layer has a thickness of between approximately 10 and approximately 20 nm.

9. The integrated circuit of claim 1, further comprising a metal reactive electrode in contact with the first solid electrolyte layer and an inert electrode in contact with the second solid electrolyte layer, wherein a conductive bridge is reversibly formed through the first solid electrolyte layer, the middle layer, and the second solid electrolyte layer when an electrical voltage is applied between the metal reactive electrode and the inert electrode.

10. The integrated circuit of claim 1, wherein the middle layer increases a temperature stability of the resistive memory element.

11. A method of manufacturing a resistive memory element, the method comprising:
depositing a first solid electrolyte layer comprising a glass material, the glass material being at least partially amorphous;
depositing a middle layer above the first solid electrolyte layer, the middle layer comprising a carbide composition; and
depositing a second solid electrolyte layer above the middle layer, the second solid electrolyte layer comprising the glass material.

12. The method of claim 11, further comprising:
depositing a metal; and
diffusing the metal into the first solid electrolyte layer, the middle layer, and the second solid electrolyte layer.

13. The method of claim 12, wherein diffusing the metal comprises using photodiffusion to diffuse the metal into the first solid electrolyte layer, the middle layer, and the second solid electrolyte layer.

14. The method of claim 12, wherein the first solid electrolyte layer is deposited above an inert electrode and wherein the method further comprises depositing a reactive metal electrode above the second solid electrolyte layer.

15. The method of claim 11, wherein depositing the middle layer comprises depositing germanium carbide or silicon carbide.

16. The method of claim 11, wherein depositing the middle layer comprises depositing a carbide composition that increases a temperature stability of the memory element.

17. The method of claim 11, wherein depositing the first solid electrolyte layer comprises depositing a glass material comprising a germanium selenide compound, a germanium sulfide compound, a silicon selenide compound or a silicon sulfide compound.

18. The method of claim 11, wherein depositing the first solid electrolyte layer comprises sputter depositing a glass material using a sputter target comprising a germanium selenide compound, a germanium sulfide compound, a silicon selenide compound or a silicon sulfide compound.

19. The method of claim 11, wherein depositing the middle layer comprises sputter depositing a carbide composition using a sputter target comprising the carbide composition.

20. The method of claim 19, wherein sputter depositing the carbide composition comprises sputter depositing a germanium carbide material using a germanium carbide sputter target or sputter depositing a silicon carbide material using a silicon carbide target.

21. The method of claim 11, wherein depositing the middle layer comprises co-sputtering the glass material with the carbide composition.

22. The method of claim 11, wherein depositing the middle layer further comprises depositing the glass material.

23. The method of claim 22, wherein depositing the glass material comprises forming impurities in the glass material that reduce an off resistance of the resistive memory element.

24. The method of claim 23, wherein forming impurities comprises forming carbon impurities or forming nitrogen impurities.

25. The method of claim 11, wherein depositing the middle layer comprises depositing the carbide composition with a thickness in the range of approximately 3 to approximately 20 nm.

26. An integrated circuit comprising:
a memory cell comprising a select transistor; and
a resistive memory element coupled to the select transistor, the resistive memory element comprising an inert electrode, a first solid electrolyte layer, a middle layer, a second solid electrolyte layer, and a metal reactive electrode,
wherein the middle layer is disposed between the first and second solid electrolyte layers, and comprises a carbide composition; and
wherein information is stored by reversibly forming a conductive bridge through the first solid electrolyte layer, the middle layer, and the second solid electrolyte layer when an electrical voltage is applied between the metal reactive electrode and the inert electrode.

27. The integrated circuit of claim 26, wherein the carbide composition in the middle layer increases a temperature stability of the resistive memory element.

28. The integrated circuit of claim 26, wherein the middle layer further comprises impurities that decrease an off resistance of the resistive memory element.

29. A method for storing information, comprising:
providing a resistive memory element comprising a first solid electrolyte layer, a middle layer, and a second solid electrolyte layer, wherein the middle layer is disposed between the first and second solid electrolyte layers, and comprises a carbide composition; and
reversibly forming a conductive bridge through the first solid electrolyte layer, the middle layer, and the second solid electrolyte layer to store information.

30. The method of claim 29, wherein providing the resistive memory element comprises providing the carbide composition in the middle layer that increases a temperature stability of the resistive memory element.

31. The method of claim 29, wherein providing the resistive memory element further comprises forming impurities in the middle layer that decrease an off resistance of the resistive memory element.

32. A memory module comprising:
a plurality of integrated circuits, wherein the integrated circuits each comprise a resistive memory element comprising a first solid electrolyte layer comprising a metal doped glass material, the metal doped glass material being at least partially amorphous;
a second solid electrolyte layer comprising the metal doped glass material; and
a middle layer disposed between the first and second solid electrolyte layers, the middle layer comprising a carbide composition.

33. The memory module of claim 32, wherein the carbide composition in the middle layer increases a temperature stability of the resistive memory element.

34. The memory module of claim 32, wherein the middle layer further comprises impurities that decrease an off resistance of the resistive memory element.

35. The memory module of claim 32, wherein the memory module is stackable.
